(19) United States
(12) Patent Application Publication
(10) Pub. No.: US 2023/0127545 A1
(43) Pub. Date: Apr. 27, 2023

(54) SEMICONDUCTOR PACKAGE DEVICE WITH HEAT-REMOVING FUNCTION AND METHOD OF MANUFACTURING SEMICONDUCTOR PACKAGE DEVICE

(71) Applicant: SHUNSIN TECHNOLOGY (ZHONG SHAN) LIMITED, Zhongshan (CN)

(72) Inventor: SHUN-HSING LIAO, Zhongshan City (CN)

(21) Appl. No.: 17/694,857

(22) Filed: Mar. 15, 2022

(30) Foreign Application Priority Data
Oct. 22, 2021 (CN) 202111234109.8

(51) Int. Cl. H01L 23/367; H01L 25/16; H01L 23/498; H01L 23/373; H01L 23/31; H01L 21/56; H01L 21/48

(52) U.S. Cl. CPC H01L 23/367; H01L 25/165; H01L 23/49816; H01L 23/49822; H01L 23/3737; H01L 23/3157; H01L 21/565; H01L 21/4857

(57) ABSTRACT

A miniaturized semiconductor package device with its own heat-dissipating ability includes a thermal conductive layer, a redistribution layer, an electronic device, a molding layer, and solder balls for connections. The redistribution layer includes a first surface, a second surface opposite to the first surface, and a circuit layer. The thermal conductive layer is disposed on the first surface of the redistribution layer. The electronic device includes an active region and a non-active region, and is disposed on the first surface of the redistribution layer and the thermal conductive layer. The molding layer is formed on the first surface and the thermal conductive layer, and surrounds the electronic device. The solder balls on the second surface of the redistribution layer electrically connect to the circuit layer.

### FIELD

The subject matter herein generally relates to temperature control for semiconductors and methods of manufacturing a device for packaging semiconductors.

### BACKGROUND

As the functions of instruments increase, semiconductor devices not only become smaller but also consume more electrical energy and give off more heat. Therefore, there is a need for a miniaturized packaging structure, which not only can reduce the relevant packaging size, but also has temperature control for reliability.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a top view of a semiconductor package device according to an embodiment of the disclosure;

FIG. 2 is a schematic cross-sectional diagram of a semiconductor package device according to an embodiment of the disclosure;

FIG. 3 is a schematic cross-sectional diagram of a semiconductor package device according to another embodiment of the disclosure;

FIG. 4 is a schematic diagram of a thermal conductive layer of the package device according to an embodiment of the disclosure.

FIG. 5 is a schematic diagram of the semiconductor package device with heat dissipation configuration according to an embodiment of the disclosure; and

FIGS. 6A, 6B, 6C, 6D and 6E are schematic cross-sectional diagrams illustrating a process flow of a method of manufacturing a semiconductor package device according to an embodiment of the disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one”.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

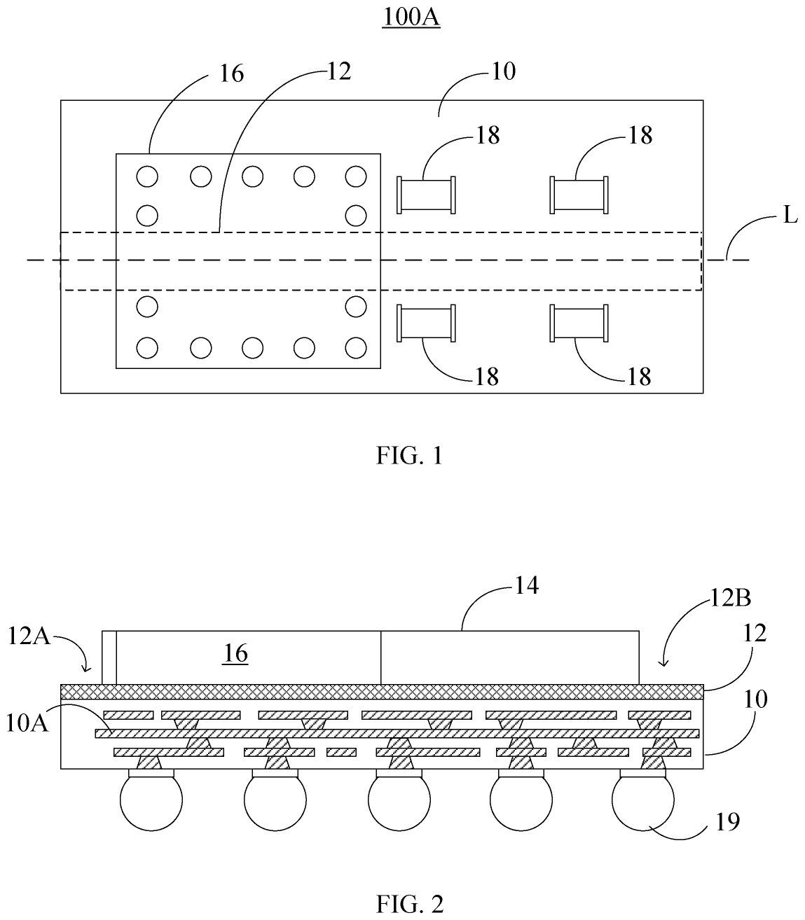

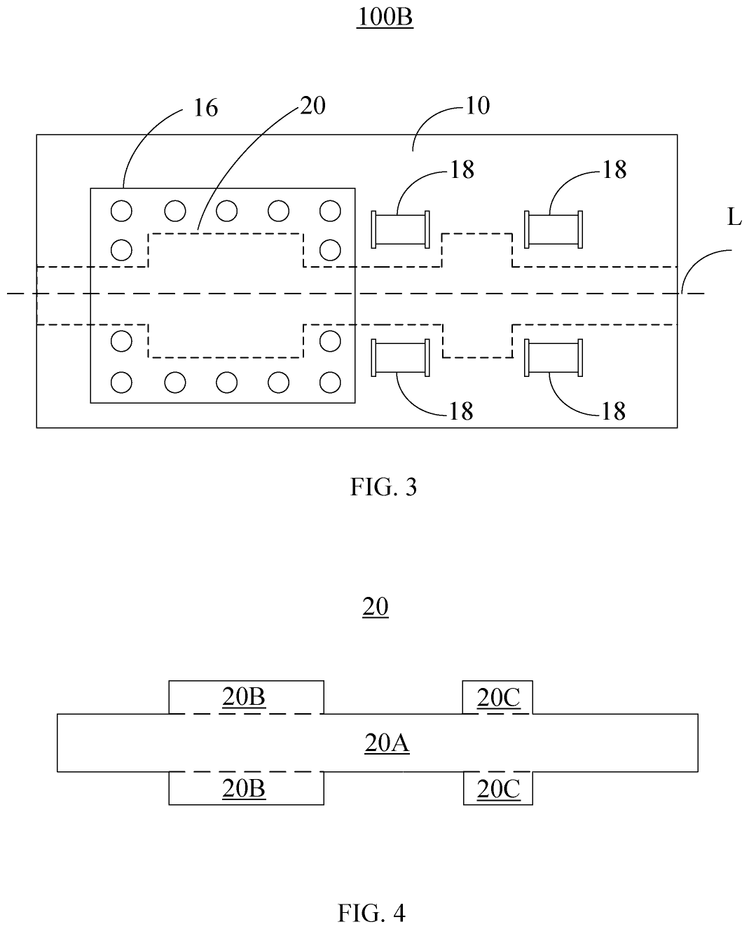

FIG. 1 illustrates a top view of a semiconductor package device according to an embodiment of the disclosure. FIG. 2 is a cross-sectional view of a semiconductor package device (semiconductor package device 100A) taken along line L of FIG. 1. The semiconductor package device 100A comprises a redistribution layer 10, a thermal conductive layer 12, a molding layer 14, an electronic device 16, electronic components 18, and solder balls 19 for electrical connection purposes. For clarity of description, in FIG. 1, the molding layer 14 and the solder balls 19 are omitted.

In FIG. 2, the redistribution layer 10 has a circuit layer 10A. According to an embodiment of the disclosure, the redistribution layer 10 can be formed layer by layer on a carrier first, then the carrier is removed after the formation of the redistributed layer 10 is completed. The formation of the redistribution layer 10 may involve multiple deposition or coating processes, patterning processes, and planarization processes. The deposition or coating processes can be used to form insulating layers or the circuit layers 10A. The deposition or coating processes may comprise a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the insulating layers and circuit layers 10A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the insulating layers and circuit layers 10A to facilitate subsequent processes. The planarization process may comprise a mechanical polishing process, a chemical mechanical polishing (CMP) process, or other applicable processes and combinations thereof.

The redistribution layer 10 can also be formed by an additive buildup process. The additive buildup process may comprise the alternating stacking of one or more dielectric layers and corresponding conductive patterns or traces of the circuit layers 10A. The conductive patterns or traces allow electrical traces out of the occupied space of the electronic device, or are in a fan-shaped layout allowing the electrical traces into the occupied space of the electronic device. The conductive patterns can be formed by a plating process such as an electroplating process or an electroless plating process. The conductive pattern may comprise a conductive material, such as copper or other plateable metals. The dielectric layer of the redistribution layer 10 can be made of a photo-definable organic dielectric such as polyimide (PI), benzocyclobutene (BCB), or polybenzoxazole (PBO). In other embodiments, the dielectric material of the redistribution layer 10 may also be an inorganic dielectric layer. The inorganic dielectric layer may comprise silicon nitride (Si₃N₄), silicon oxide (SiO₂), or SiON. The inorganic dielectric layer can be formed by growing an inorganic dielectric layer using an oxidation or nitridation process.

According to the embodiment of the disclosure, the redistribution layer 10 may further comprise a carrier, for example, a printed circuit board (PCB) or a laminated substrate. The carrier can be formed by laminating and build-up methods, which are wholly conventional and will be fully appreciated by those of ordinary skill in the art. The material of the dielectric structure inside the carrier may comprise epoxy resin, phenolic resin, glass epoxy resin, polyimide, polyester, epoxy molding compound, or ceramic. The material of the wires inside the carrier may comprise copper, iron, nickel, gold, silver, palladium, or tin.

The thermal conductive layer 12 is in a shape of a strip and is disposed on the redistribution layer 10. The thermal conductive layer 12 is formed of a material with high thermal conductivity. The thermal conductivity can be in the range of 50 to 5300 W/mK. According to an embodiment of the disclosure, the material of the thermal conductive layer 12 may comprise copper, copper alloy, ceramic, graphene, graphite, carbon nanotube (CNT), carbon nanospheres, and aluminum nitride (AlN), or a combination thereof. As shown in FIG. 2, the thermal conductive layer 12 is not completely covered by the electronic device 16, portions 12A and 12B of the thermal conductive layer 12 extend beyond the sidewall of the electronic device 16.

The bottom (second surface) of the redistribution layer 10 has solder balls 19 electrically connected to the circuit layer 10A. The solder balls 19 can be implanted on the bottom of the redistribution layer 10 by ball implantation. The semiconductor package device 100A according to an embodiment of the disclosure can be electrically connected to an external device (such as a printed circuit board) by these solder balls 19.

As shown in FIG. 1, an electronic device 16 and electronic components 18 are provided on the top (first side) of the redistribution layer 10. In FIG. 1, a single electronic device 16 and four electronic components 18 are shown. However, the actual number is not limited to these, and those skilled in the art can set a specific number of electronic devices 16 and electronic components 18 according to actual needs. The electronic device 16 may be a semiconductor die, a semiconductor chip, or a package including a plurality of electronic devices. The electronic device 16 includes an active region electrically connected to external electrical elements and a non-active region electrically isolated from the external electrical elements. The non-active region can be an insulating layer. The thermal conductive layer 12 is in contact with the non-active region of the electronic device 16 to remove heat generated by the electronic device 16 through conduction.

The electronic device 16 may be connected to the circuit layer 10A of the redistribution layer 10 via conductive wires such as gold wires, copper wires, or aluminum wires. The electronic device 16 may be optoelectronic devices, micro-electromechanical systems (MEMS), power amplifier chips, power management chips, biological identification devices, microfluidic systems, or a physical sensor that measures changes in physical quantities such as heat, light, and pressure. The electronic device 16 also can also comprise semiconductor chips such as imaging sensor devices, light-emitting diodes (LEDs), solar cells, accelerators, gyroscopes, fingerprint readers, micro actuators, surface acoustic wave devices, process sensors, or ink printer heads made by a wafer scale package (WSP) process. The electronic components 18 may be electrically connected to the circuit layer 10A of the redistribution layer 10. According to an embodiment of the disclosure, an electronic component 18 may be a passive component, such as a resistor, a capacitor, an inductor, a filter, an oscillator, and so on. In other embodiments, the electronic component 18 may also be a terminal for other connections.

The electronic device 16 and the electronic components 18 can be disposed on the top (first side) of the redistribution layer 10 by a flip-chip packaging, and are electrically connected to the circuit layer 10A in the redistribution layer 10. In addition, the electronic device 16 and the electronic components 18 can also be disposed on the top (first side) of the redistribution layer 10 through an adhesive layer, and electrically connected to the circuit layer 10A in the redistribution layer 10 by wire bonding.

According to an embodiment of the disclosure, the adhesive layer can be formed of various materials, including a polyimide (PI), polyethylene terephthalate (PET), Teflon, liquid crystal polymer (LCP), polyethylene (PE), polypropylene (PP), polystyrene (PS), polyvinyl chloride (PVC), nylon or polyamides, polymethylmethacrylate (PMMA), acrylonitrile-butadiene-styrene, phenolic resins, epoxy resin, polyester, silicone, polyurethane (PU), polyamide-imide (PAI) or a combination thereof, not being limited thereto, as long as such materials have the required adhesive properties.

As shown in FIG. 2, the molding layer 14 is formed on the redistribution layer 10, surrounds the electronic device 16, and exposes the top surface of the electronic device 16. The molding layer 14 also covers the electronic components 18 and the thermal conductive layer 12, but does not cover portions 12A and 12B of the thermal conductive layer 12. According to an embodiment of the disclosure, the material of the molding layer 14 can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

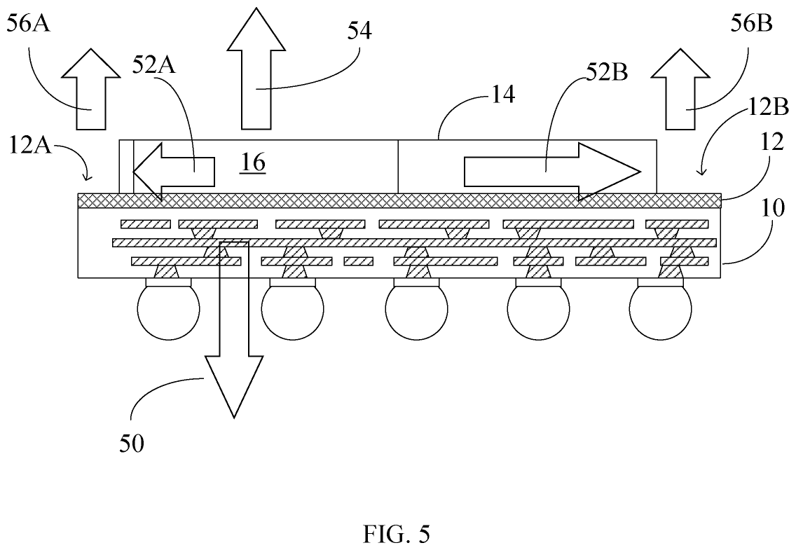

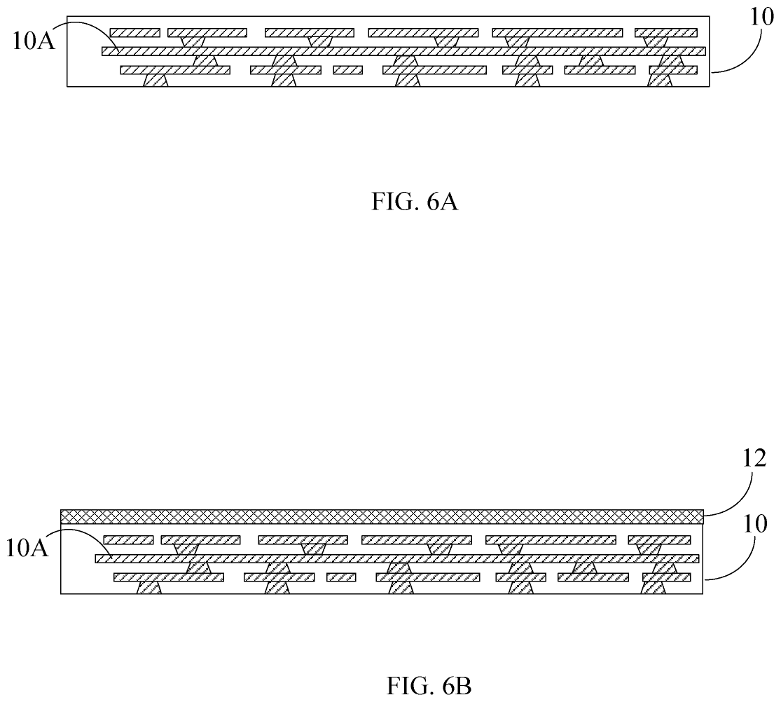

FIG. 3 illustrates a semiconductor package device according to another embodiment of the disclosure (semiconductor package device 100B). The difference between the semiconductor package device 100B and the semiconductor package device 100A shown in FIG. 1 is that the protruding regions are added to the elongated region of the thermal conductive layer 20. FIG. 4 shows a schematic diagram of the thermal conductive layer 20 according to an embodiment of the disclosure. The thermal conductive layer 20 comprises an elongated region 20A and a plurality of protruding regions 20B and 20C. The protruding regions 20B are located on both sides of the elongated region 20A. Similarly, the protruding regions 20C are located on both sides of the elongated region 20A, and the protruding regions 20B and 20C are coplanar with the elongated region 20A. According to an embodiment of the disclosure, the protruding regions 20B are in contact with the non-active region of the electronic device 16, so as to remove heat of the electronic device 16 through conduction. The protruding regions 20C are located between the two electronic components 18, which helps to dissipate the heat of the redistribution layer 10. The remaining structure of the semiconductor package device 100B is the same as that of the semiconductor package device 100A shown in FIG. 1.

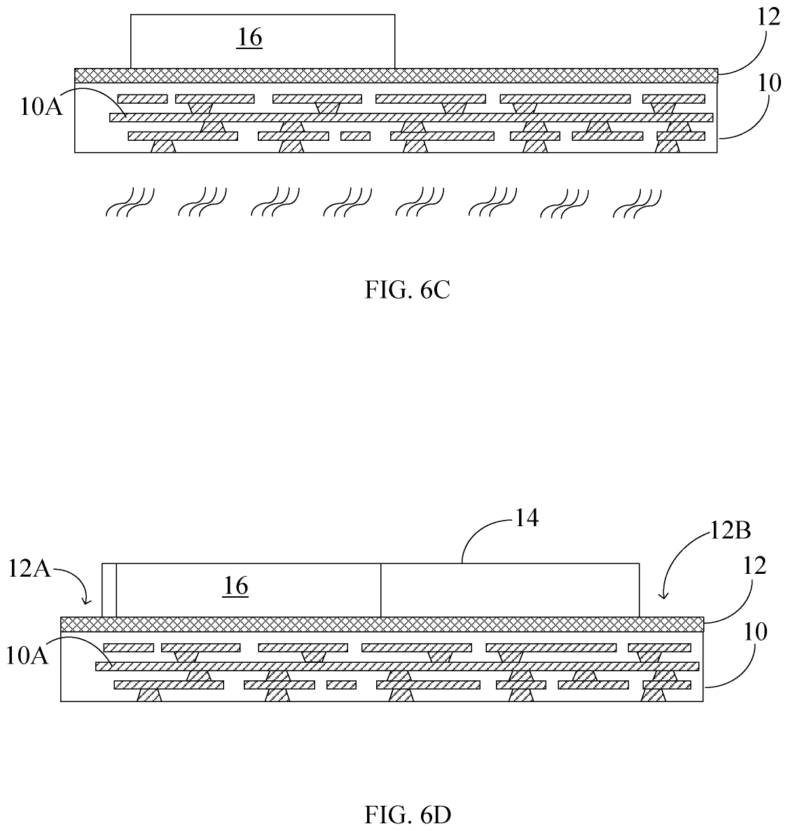

FIG. 5 illustrates heat dissipation layout of the semiconductor package device according to an embodiment of the disclosure. As shown in FIG. 5, the heat generated by the electronic device 16 can be dissipated from the heat dissipation direction 50 to the bottom of the redistribution layer 10, and dissipated in heat dissipation directions 52A, 52B toward both sides of the electronic device 16 through the thermal conductive layer 12, then being dissipated toward the upper side of the electronic device 16 in heat dissipation direction 54. Since portions 12A and 12B of the thermal conductive layer 12 are not covered by the molding layer 14, the heat can also be dissipated in heat dissipation directions 56A and 56B, thereby effectively improving the heat dissipation efficiency of the semiconductor package device. In addition, since the thermal conductivity of the molding layer 14 is 3-5 W/m*K, and the circuit layer 10A of the redistribution layer 10 has a small heat dissipation area, the thermal conductivity of the thermal conductive layer 12 made of graphene is 800 W/m*K or more, so the heat dissipation efficiency of the semiconductor package device is improved. Moreover, the thermal conductive layer 12 attached to the redistribution layer 10 increases the toughness of the redistribution layer 10 to prevent the redistribution layer 10 from cracking, further improving the reliability of the product.

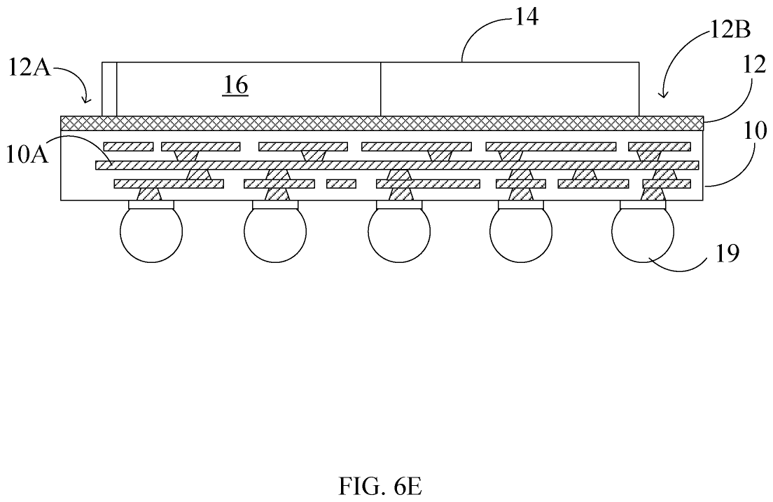

FIGS. 6A-6E illustrate other embodiments for implementation of the method of the disclosure. In FIG. 6A, a redistribution layer 10 is provided. The redistribution layer 10 comprises a circuit layer 10A. According to an embodiment of the disclosure, the redistribution layer 10 can be formed layer by layer on a carrier first, then the carrier is removed after the formation of the redistributed layer 10 is completed. The formation of the redistribution layer 10 may involve multiple deposition or coating processes, patterning processes, and planarization processes. The deposition or coating processes can be used to form insulating layers or the circuit layers 10A. The deposition or coating processes may comprise a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the formed insulating layers and circuit layers 10A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the formed insulating layers and circuit layers 10A to facilitate subsequent processes. The planarization process may comprise a mechanical polishing process, a chemical mechanical polishing (CMP) process, or other applicable processes and combinations thereof.

The redistribution layer 10 can also be formed by an additive buildup process. The additive buildup process may comprise the alternating stacking of one or more dielectric layers and conductive patterns or traces of the circuit layers 10A. The conductive patterns or traces allow the electrical traces out of the occupied space of the electronic device, or can fan the electrical traces into the occupied space of the electronic device. The conductive patterns can be formed by a plating process such as an electroplating process or an electroless plating process. The conductive pattern may comprise a conductive material, such as copper or other plateable metals. The dielectric layer of the redistribution layer 10 can be made of a photo-definable organic dielectric such as polyimide (PI), benzocyclobutene (BCB), or polybenzoxazole (PBO). In other embodiments, the dielectric material of the redistribution layer 10 may also be an inorganic dielectric layer. The inorganic dielectric layer may comprise silicon nitride (Si₃N₄), silicon oxide (SiO₂), or SiON. The inorganic dielectric layer can be formed by growing an inorganic dielectric layer using an oxidation or nitridation process.

According to the embodiment of the disclosure, the redistribution layer 10 may further comprise a carrier, for example, a printed circuit board (PCB) or a laminated substrate. The carrier can be formed by laminated and build-up methods, which are wholly conventional. The material of the dielectric structure inside the carrier may comprise epoxy resin, phenolic resin, glass epoxy resin, polyimide, polyester, epoxy molding compound, or ceramic. The material of the wires inside the carrier may comprise copper, iron, nickel, gold, silver, palladium, or tin.

Next, as shown in FIG. 6B, the thermal conductive layer 12 is disposed on the redistribution layer 10 and is formed of a material with high thermal conductivity. The thermal conductivity can be in the range of 50 to 5300 W/mK. According to an embodiment of the disclosure, the material of the thermal conductive layer 12 may comprise copper, copper alloy, ceramic, graphene, graphite, carbon nanotube (CNT), carbon nanospheres, and aluminum nitride (AlN), or a combination thereof.

Next, as shown in FIG. 6C, an electronic device 16 is disposed on the thermal conductive layer 12. In FIG. 6C, only a single electronic device 16 is shown. However, the actual number is not limited thereto, and those skilled in the art can set a specific number of electronic devices 16A according to actual needs. The electronic device 16 may be a semiconductor die, a semiconductor chip, or a package containing a plurality of electronic devices. The electronic device 16 includes an active region electrically connected to external electrical elements and a non-active region electrically isolated from the external electrical elements. The non-active region can be an insulating layer. The thermal conductive layer 12 is in contact with the non-active region of the electronic device 16 to remove the heat of the electronic device 16 through conduction. The electronic device 16 may be connected to the circuit layer 10A of the redistribution layer 10 via conductive wires such as gold wires, copper wires, or aluminum wires. The electronic device 16 may be optoelectronic devices, micro-electromechanical systems (MEMS), power amplifier chips, power management chips, biological identification devices, microfluidic systems, or a physical sensor that measures changes in physical quantities such as heat, light, and pressure. The electronic device 16 also can also comprise semiconductor chips such as imaging sensor devices, light-emitting diodes (LEDs), solar cells, accelerators, gyroscopes, fingerprint readers, micro actuators, surface acoustic wave devices, process sensors, or ink printer heads made by a wafer scale package (WSP) process.

The electronic device 16 can be disposed on the thermal conductive layer 12 by a flip-chip packaging, and is electrically connected to the circuit layer 10A in the redistribution layer 10. In addition, the electronic device 16 can also be disposed on the thermal conductive layer 12 through an adhesive layer, and electrically connected to the circuit layer 10A in the redistribution layer 10 by wire bonding.

According to an embodiment of the disclosure, the adhesive layer can be formed of various materials, including a polyimide (PI), polyethylene terephthalate (PET), Teflon, liquid crystal polymer (LCP), polyethylene (PE), polypropylene (PP), polystyrene (PS), polyvinyl chloride (PVC), nylon or polyamides, polymethylmethacrylate (PMMA), acrylonitrile-butadiene-styrene, phenolic resins, epoxy resin, polyester, silicone, polyurethane (PU), polyamide-imide (PAI) or a combination thereof, not being limited thereto, as long as such materials have the required adhesive properties. Next, the semi-finished product is baked to cure the adhesive layer to fix the electronic device 16 on the thermal conductive layer 12.

Next, in FIG. 6D, the molding layer 14 is formed on the redistribution layer 10 and covers the electronic device 16. The molding layer 14 also covers the thermal conductive layer 12, except for the portions 12A and 12B of the thermal conductive layer 12. The molding layer 14 is then polished by a planarization process until the top of the electronic device 16 is exposed. According to the embodiment of the disclosure, the planarization process may comprise a mechanical polishing process, a chemical mechanical polishing (CMP) process, or other applicable processes and combinations thereof. According to an embodiment of the disclosure, the material of the molding layer 14 can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

Finally, in FIG. 6E, solder balls 19 are placed on the bottom (second surface) of the redistribution layer 10 and electrically connected to the circuit layer 10A. The solder balls 19 can be implanted on the bottom of the redistribution layer 10 by ball implantation. The semiconductor package device according to an embodiment of the disclosure can be electrically connected to an external device (such as a printed circuit board) by these solder balls 19.

According to the embodiments of the disclosure, the heat dissipation efficiency of the semiconductor package device is improved by the thermal conductive layer. The thermal energy generated by the electronic device 16 can be quickly dissipated from the heat dissipation direction 50 to the bottom of the redistribution layer 10, and dissipated from the heat dissipation directions 52A, 52B toward both sides of the electronic device 16 via the thermal conductive layer 12, then being dissipated toward the upper side of the electronic device 16 via the heat dissipation direction 54. Since portions 12A and 12B of the thermal conductive layer 12 are not covered by the molding layer 14, the heat can also be dissipated in heat dissipation directions 56A and 56B, thereby effectively improving the heat dissipation efficiency of the semiconductor package device. In addition, stresses on the thermal conductive layer 10 such as hot-cold cycling are higher than those of the redistribution layer 10. The redistribution layer 12 attached to the thermal conductive layer 10 prevents the redistribution layer 12 from cracking, improving the reliability of the semiconductor products.

Many details are often found in the relevant art and many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A semiconductor package device comprising:
a redistribution layer comprising a first surface, a second surface opposite to the first surface, and a circuit layer;
a thermal conductive layer disposed on the first surface of the redistribution layer;
an electronic device comprising an active region and a non-active region, the electronic device disposed on the first surface of the redistribution layer and the thermal conductive layer;
an electronic component disposed on the first surface of the redistribution layer;
a molding layer formed on the first surface and the thermal conductive layer, the molding layer surrounding the electronic device and covering the electronic component; and
a solder ball disposed on the second surface of the redistribution layer and electrically connected to the circuit layer.

2. The semiconductor package device of claim 1, wherein a material of the thermal conductive layer is copper, copper alloy, ceramic, graphene, graphite, carbon nanotube (CNT), or carbon nanospheres.

3. The semiconductor package device of claim 1, wherein the thermal conductive layer has a shape of a strip, the thermal conductive layer is in contact with the non-active region.

4. The semiconductor package device of claim 1, wherein the thermal conductive layer comprises an elongated region and a plurality of protruding regions, and the thermal conductive layer is in contact with the non-active region.

5. The semiconductor package device of claim 4, wherein the protruding regions are located on both sides of the elongated region, and the protruding regions are coplanar with the elongated region.

6. A semiconductor package device comprising:
a redistribution layer comprising a first surface, a second surface opposite to the first surface, and a circuit layer;
a thermal conductive layer disposed on the first surface of the redistribution layer;
an electronic device disposed on the first surface of the redistribution layer, and comprising an active region and a non-active region, wherein the non-active region is in contact with the thermal conductive layer;
an electronic component disposed on the first surface of the redistribution layer;
a molding layer formed on the first surface and the thermal conductive layer, the molding layer surrounding the electronic device and covering the electronic component; and
a solder ball disposed on the second surface of the redistribution layer and electrically connected to the circuit layer.

7. The semiconductor package device of claim 6, wherein a material of the thermal conductive layer is copper, copper alloy, ceramic, graphene, graphite, carbon nanotube (CNT), or carbon nanospheres.

8. The semiconductor package device of claim 6, wherein the thermal conductive layer has a shape of a strip.

9. The semiconductor package device of claim 6, wherein the thermal conductive layer comprises an elongated region and a plurality of protruding regions.

10. The semiconductor package device of claim 9, wherein the protruding regions are located on both sides of the elongated region, and the protruding regions are coplanar with the elongated region.

11. A method of manufacturing a semiconductor package device, the method comprising:
providing a redistribution layer comprising a first surface, a second surface opposite to the first surface, and a circuit layer;
disposing a thermal conductive layer on the first surface of the redistribution layer;
disposing an electronic device on the first surface of the redistribution layer and the thermal conductive layer, wherein the electronic device comprises an active region and a non-active region;
disposing an electronic component on the first surface of the redistribution layer;
forming a molding layer on the first surface and the thermal conductive layer, and the molding layer covering the electronic device and the electronic component;
polishing the molding layer to expose a top of the electronic device; and
disposing a solder ball on the second surface of the redistribution layer and electrically connected to the circuit layer.

12. The method of claim 11, wherein a material of the thermal conductive layer is copper, copper alloy, ceramic, graphene, graphite, carbon nanotube (CNT), or carbon nanospheres.

13. The method of claim 11, wherein disposing the thermal conductive layer further comprising configuring the thermal conductive layer to be elongated and in contact with the non-active region.

14. The method of claim 11, wherein disposing the thermal conductive layer further comprising configuring the thermal conductive layer to comprise an elongated region and a plurality of protruding regions, and contacting the thermal conductive layer with the non-active region.

15. The method of claim 14, further comprising positioning the protruding regions on both sides of the elongated region, and the protruding regions being coplanar with the elongated region.
